(19) United States
(12) Patent Application Publication
(10) Pub. No.: US 2014/0048790 A1
(43) Pub. Date: Feb. 20, 2014

(54) ORGANIC EL ELEMENT, TRANSLUCENT SUBSTRATE AND METHOD OF MANUFACTURING ORGANIC LED ELEMENT

(71) Applicant: ASAHI GLASS COMPANY, LIMITED, Tokyo (JP)

(72) Inventors: Masamichi TANIDA, Tokyo (JP); Nao Ishibashi, Tokyo (JP); Nobuhiro Nakamura, Tokyo (JP)

(73) Assignee: ASAHI GLASS COMPANY, LIMITED, Tokyo (JP)

(21) Appl. No.: 14/062,569

(22) Filed: Oct. 24, 2013

Related U.S. Application Data
(63) Continuation of application No. PCT/JP2012/060842, filed on Apr. 23, 2012.

(30) Foreign Application Priority Data
Apr. 28, 2011 (JP) 2011-101846

(51) Int. Cl. H01L 51/52; H05K 1/03; H05K 1/09; H01L 51/56

(52) U.S. Cl. CPC H01L 51/5268; H01L 51/5215; H01L 51/56; H05K 1/0306; H05K 1/09
USPC 257/40; 438/29; 174/258; 174/257

(57) ABSTRACT

An organic LED element includes a transparent substrate, a light scattering layer, a first electrode, an organic light emitting layer, and a second electrode. The light scattering layer includes a base material made of glass, and scattering substances dispersed in the base material. The light scattering layer has a refractive index [N″] greater than a refractive index [N′] of the transparent substrate. First and second layers made of a material other than molten glass are arranged between the light scattering layer and the first electrode. A refractive index N₁ of the first layer is greater than [N′], and a refractive index N₂ of the second layer is greater than each of [N′], [N″], and N₁.

### CROSS-REFERENCE TO RELATED APPLICATIONS

This application is a continuation application of International Application No. PCT/JP2012/060842 filed on Apr. 23, 2012 and designated the U.S., which is based upon and claims the benefit of priority of Japanese Patent Application No. 2011-101846 filed on Apr. 28, 2011 to the Japan Patent Office, the entire contents of which are incorporated herein by reference.

### BACKGROUND OF THE INVENTION

1. Field of the Invention

The present invention relates to organic EL element, a translucent substrate and a method of manufacturing an organic LED element.

2. Description of the Related Art

An organic Electro Luminescence (organic EL) element is widely used for a display, a backlight, an illumination, and the like.

A general purpose organic EL element includes a first electrode (anode) formed on a substrate, a second electrode (cathode), and an organic layer provided between these electrodes. When a voltage is applied between the electrodes, holes and electrons are injected into the organic layer from each of the electrodes. When the holes and the electrodes are recombined in the organic layer, a binding energy is generated to excite luminescent materials in the organic layer. Since light emissions occur when the excited luminescent materials return to the ground state, a luminescence (EL) element may be obtained by using this phenomenon.

Generally, a transparent thin layer made of a material, such as Indium Tin Oxide (hereinafter simply referred to as “ITO”) may be used for the first electrode, that is, the anode, and a metal thin layer made of a metal such as aluminum, silver, or the like may be used for the second electrode, that is, the cathode.

Recently, there is a proposal to provide a light scattering layer including scattering substances between the ITO electrode and the substrate (for example, International Publication WO2009/017035). In such a structure, a part of the light emissions occurring in the organic layer may be scattered by the scattering substances in the light scattering layer so that the amount of light trapped in the ITO electrode or the substrate (the amount of light of total reflection) may be decreased to increase a light extracting efficiency of the organic EL element.

As described above, the proposed organic EL element includes the light scattering layer formed on the transparent substrate. However, there may be cases in which the light extracting efficiency is desirably even higher than the light extracting efficiency of the organic EL element proposed in the International Publication WO2009/017035.

### SUMMARY OF THE INVENTION

The present invention is conceived in view of the above problem, and an object of the present invention is to provide an organic EL element in which the light extracting efficiency is improved over that of the conventional element. Further, an object of the present invention is to provide a translucent substrate for use in such an organic EL element, and a method of manufacturing an organic LED element.

One embodiment of the present invention provides an organic LED element including a transparent substrate, a light scattering layer formed on the transparent substrate, a transparent first electrode formed on the light scattering layer, an organic light emitting layer formed on the first electrode, and a second electrode formed on the organic light emitting layer,

wherein the light scattering layer includes a base material made of glass, and a plurality of scattering substances dispersed in the base material, wherein the light scattering layer has a refractive index [N″] greater than a refractive index [N′] of the transparent substrate;

a first layer and a second layer are arranged between the light scattering layer and the first electrode, such that the first layer is closer to the light scattering layer than the second layer;

the first layer is made of a material other than molten glass, and has a first refractive index N₁;

the second layer is made of a material other than the molten glass, and has a second refractive index N₂;

the first refractive index N₁ is greater than the refractive index [N′] of the transparent substrate; and

the second refractive index N₂ is greater than each of the refractive index [N′] of the transparent substrate, the refractive index [N″] of the light scattering layer, and the first refractive index N.

In the organic LED element according to one embodiment of the present invention, the refractive index [N″] of the light scattering layer may be greater than the first refractive index N.

In addition, in the organic LED element according to one embodiment of the present invention, the first layer and/or the second layer may be made of a metal oxide.

Further, one embodiment of the present invention provides a translucent substrate comprising:

a transparent substrate;

a light scattering layer formed on the transparent substrate;

a first layer formed on the light scattering layer;

a second layer formed on the first layer; and

a transparent first electrode formed on the second layer;

wherein the light scattering layer includes a base material made of glass, and a plurality of scattering substances dispersed in the base material, wherein the light scattering layer has a refractive index [N″] greater than a refractive index [N′] of the transparent substrate;

the first layer is made of a material other than molten glass, and has a first refractive index N₁;

the second layer is made of a material other than the molten glass, and has a second refractive index N₂;

the first refractive index N₁ is greater than the refractive index [N′] of the transparent substrate; and

the second refractive index N₂ is greater than each of the refractive index [N′] of the transparent substrate, the refractive index [N″] of the light scattering layer, and the first refractive index N.

In addition, one embodiment of the present invention provides a method of manufacturing an organic LED element including a transparent substrate, a light scattering layer formed on the transparent substrate, a transparent first electrode formed on the light scattering layer, an organic light emitting layer formed on the first electrode, and a second electrode formed on the organic light emitting layer, the method comprising:

forming a first layer and a second layer between the light scattering layer and the first electrode;

wherein the first layer is formed by a wet coating process at a position closer to the light scattering layer than the second layer, using a material other than molten glass and having a first refractive index N₁;

the second layer is formed using a material other than the molten glass and having a second refractive index N₂;

the light scattering layer includes a base material made of glass, and a plurality of scattering substances dispersed in the base material, and has a refractive index [N″] greater than a refractive index [N′] of the transparent substrate;

the first refractive index N₁ is greater than the refractive index [N′] of the transparent substrate; and

the second refractive index N₂ is greater than each of the refractive index [N′] of the transparent substrate, the refractive index [N″] of the light scattering layer, and the first refractive index N.

Other objects and further features of the present invention may be apparent from the following detailed description when read in conjunction with the accompanying drawings.

### BRIEF DESCRIPTION OF THE DRAWINGS

FIG. 1 is a cross sectional view schematically illustrating an example of a structure of an organic EL element in one embodiment of the present invention;

FIG. 2 is a schematic flow chart of a method of manufacturing the organic EL element in one embodiment of the present invention;

FIG. 3 is a schematic diagram for explaining a problem when forming each layer on top of a light scattering layer;

FIG. 4 is a diagram schematically illustrating an example of a layer configuration when a first layer is formed by a wet coating process;

FIG. 5 is a cross sectional view schematically illustrating a structure of an LED element used for simulation in a practical example 1; and

FIG. 6 is a cross sectional view schematically illustrating the structure of the LED element used for simulation in a practical example 2.

### DESCRIPTION OF THE PREFERRED EMBODIMENTS

A detailed description will hereinafter be given of embodiments of the present invention with reference to the drawings.

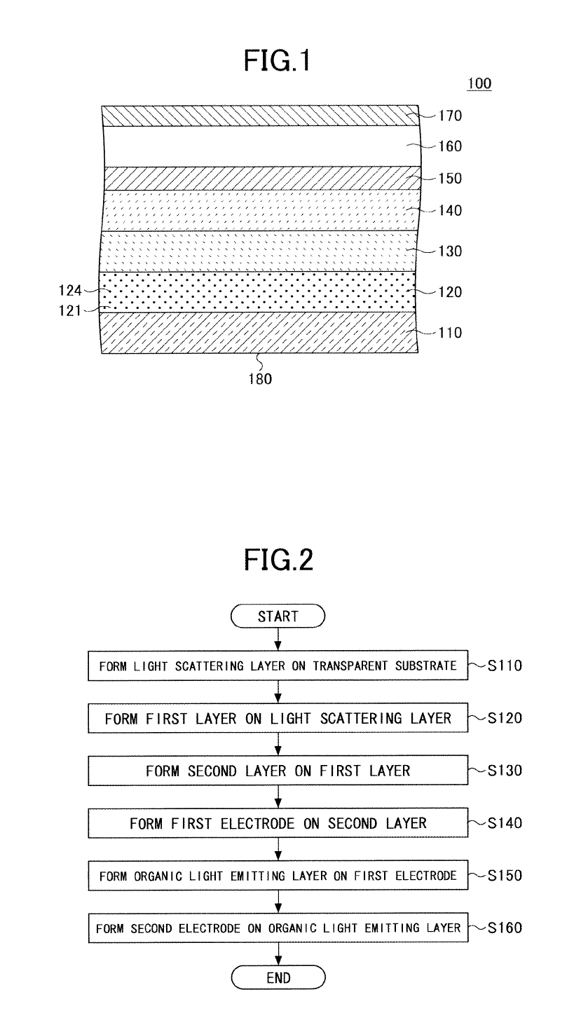

FIG. 1 is a cross sectional view schematically illustrating an example of a structure of an organic EL element in one embodiment of the present invention.

As illustrated in FIG. 1, an organic EL element 100 in one embodiment of the present invention is formed by a transparent substrate 110, a light scattering layer 120, a first layer 130, a second layer 140, a first electrode (anode) 150, an organic light emitting layer 160, and a second electrode (cathode) 170 that are stacked in this order. In the example illustrated in FIG. 1, a lower surface of the organic EL element 100 (that is, an exposed surface of the transparent substrate 110) forms a light extraction surface 180.

The transparent substrate 110 is formed by a glass substrate or a plastic substrate, for example. The transparent substrate 110 has a refractive index [N′].

The first electrode 150 is made of a transparent metal oxide thin film, such as ITO, for example, and has a thickness on the order of 50 nm to 1.0 μm. On the other hand, the second electrode 170 is made of a metal, such as aluminum or silver, for example.

Generally, the organic light emitting layer 150 is formed by a plurality of layers, such as an electron transport layer, an electron injection layer, a hole transport layer, a hole injection layer, and the like, in addition to a light emitting layer.

The light scattering layer 120 includes a base material 121 made of glass and having a certain refractive index, and a plurality of scattering substances 124 dispersed in the base material 121 and having a refractive index different from that of the base material 121. The thickness of the light scattering layer 120 is in a range of 5 μm to 50 μm, for example. The light scattering layer 120 has a function to reduce reflection of light at an interface between a layer adjacent to the light scattering layer 120, by scattering incident light.

The light scattering layer 120 has a refractive index [N″]. The refractive index [N″] is greater than the refractive index [N′] of the transparent substrate 110.

One feature of the organic EL element in the embodiment is that the organic EL element includes two different layers (the first layer 130 and the second layer 140) between the light scattering layer 120 and the first electrode 150.

The first layer 130 is made of a material other than molten glass, and has a first refractive index N. The second layer 140 is made of a material other than molten glass and different from the material used for the first layer 130, and has a second refractive index N₂.

In addition, one feature of the organic EL element is that the first refractive index N₁ of the first layer 130 is greater than the refractive index [N′] of the transparent substrate 110, and the second refractive index N₂ of the second layer 140 is the greatest amongst the refractive index [N′] of the transparent substrate 110, the refractive index [N″] of the light scattering layer 120, and the first refractive index N₁ of the first layer 130.

In this application, unless otherwise indicated, the “refractive index” refers to a refractive index Nd (real part of complex refractive index) for d-line having a wavelength of 588 nm.

In a case in which the first layer 130 and the second layer 140 having the feature described above are arranged between the light scattering layer 120 and the first electrode 150, a preferable interference state may be obtained, and as a result, an angle dependence of light incident to the light scattering layer may be more desirable, when compared to a case in which only the second layer is provided. More particularly, the interference caused by multiple reflection between the cathode 170 and the second layer 140 may be reduced, and the angle dependence of the wavelength of the light incident to the light scattering layer may be reduced, in order to suppress a change in hue depending on the angle.

For this reason, according to the organic EL element 100 in the embodiment, a light extraction efficiency with which light may be extracted from the light extraction surface 180 may be increased when compared to the conventional case.

In addition, in a case in which the base material 121 of the transparent substrate 110 and/or the light scattering layer 120 is made of glass (for example, soda-lime glass or the like) including alkali metal, the first layer 130 and/or the second layer 140 may function as a barrier layer between the light scattering layer 120 and the first electrode 150. In other words, in the conventional organic EL element in which the first layer 130 and the second layer 140 do not exist, the alkali metal in the light scattering layer 120 may move relatively easily towards the side of the first electrode. Such a movement of the alkali metal causes characteristics (for example, transparency, electrical conductivity, and the like) of the first electrode to deteriorate. However, in the case in which the first layer 130 and/or the second layer 140 may function as the barrier layer in the organic EL element 100 in the embodiment, the movement of the alkali metal from the light scattering layer 120 towards the first electrode 150 may be suppressed.

Next, a detailed description will be given of each layer forming the organic EL element in the embodiment.

(Transparent Substrate 110)

The transparent substrate 110 is made of a material having a high transmittance with respect to visible light. The transparent substrate 110 may be a glass substrate or a plastic substrate, for example.

The refractive index [N′] of the transparent substrate 110 may be in a range of 1.5 to 1.8, for example.

The material used for the glass substrate may be inorganic glass, such as alkali glass, alkali-free glass, quartz glass, and the like. The material used for the plastic substrate may be polyester, polycarbonate, polyether, polysulfone, polyether sulfone, polyvinyl alcohol, and fluorine-containing polymer, such as polyvinylidene fluoride, polyvinyl fluoride, or the like.

The thickness of the transparent substrate 110 is not limited to a particular value, and may be in a range of 0.1 mm to 2.0 mm, for example. When the strength and weight are taken into consideration, the thickness of the transparent substrate 110 is preferably 0.5 mm to 1.4 mm.

(Light Scattering Layer 120)

The light scattering layer 120 includes the base material 121 and the plurality of scattering substances 124 dispersed in the base material 121. The base material 121 has a certain refractive index, and the scattering substances 124 have a refractive index different from that of the base material.

As described above, one feature of the organic EL element is that the refractive index [N″] of the light scattering layer 120 is greater than the refractive index [N′] of the transparent substrate 110. The refractive index [N″] of the light scattering layer 120 is in a range of 1.6 to 2.2, for example.

The scattering substances 124 may be made of pores of a material, precipitated crystals, particles of a material different from those of the base material, phase separated glass, and the like. The phase separated glass refers to glass composed of two or more kinds of glass phases.

The difference between the refractive index of the base material 121 and the refractive index of the scattering substances 124 is preferably large, and in order to obtain the large difference, high refractive index glass may preferably be used for the base material 121 and pores of the material may preferably be used for the scattering substances 124.

For the high refractive index glass used for the base material 121, one or more components may be selected from P₂O₅, SiO₂, B₂O₃, GeO₂, and TeO₂ as a network former, and one or more components may be selected from TiO2, Nb₂O₅, WO₃, Bi₂O₃, La₂O₃, Gd₂O₃, Y₂O₃, ZrO₂, ZnO, BaO, PbO, and Sb₂O₃ as a high refractive index component. Further, in order to adjust characteristics of the glass, alkali oxide, alkaline earth oxide, fluoride, or the like may be added within a range not affecting the refractive index.

Accordingly, the glass system forming the base material 121 may be a B₂O₃—ZnO—La₂O₃ system, a P₂O₅—B₂O₃—R′₂O—R″O—TiO₂—Nb₂O₅—WO₃—Bi₂O₃ system, a TeO₂—ZnO system, a B₂O₃—Bi₂O₃ system, a SiO₂—Bi₂O₃ system, a SiO₂—ZnO system, a B₂O₃—ZnO system, a P₂O₅—ZnO system, or the like, for example. Here, R′ represents an alkali metal element and R″ represents an alkaline earth metal element. The above material systems are merely examples, and the material used for the base material is not limited to a particular material as long as the material satisfies the above described conditions.

By adding a colorant to the base material 121, the color of light that is emitted may be changed. The colorant may use one of or a combination of transition metal oxide, rare earth metal oxide, metal colloid, and the like.

According to the organic EL element 100 in the embodiment, fluorescent substances may be used for the base material 121 or the scattering substances 124. In this case, it is possible to change the color of the light emission from the organic light emitting layer 160 by a wavelength conversion. In addition, in this case, it is possible to reduce the light emission colors of the organic EL element, and because the emitted light is extracted after being scattered, the angle dependency of the color and/or changes in color with time may be suppressed. Such a structure may suitably applied for use in a backlight or illumination requiring white light emission.

(First Layer 130)

As described above, one feature of the organic EL element is that the refractive index N₁ of the first layer 130 is greater than the refractive index [B′] of the transparent substrate 110. The refractive index N₁ of the first layer 130 is in a range of 1.55 to 2.3, for example. The refractive index N₁ of the first layer 130 may be smaller than or greater than the refractive index [N″] of the light scattering layer. However, the refractive index N₁ of the first layer 130 needs to be smaller than the refractive index N₂ of the second layer 140.

The first layer 130 is made of a material other than molten glass. The first layer 130 may be made of a metal oxide, such as titanium oxide, niobium oxide, zirconium oxide, and tantalum oxide, for example.

A method of forming the first layer 130 is not limited to a particular method. For example, the first layer 130 may be formed by a dry coating process, such as PVD and CVD, or a wet coating process, such as dipping and sol-gel process.

The thickness of the first layer 130 is not limited to a particular thickness. For example, the thickness of the first layer 130 may be in a range of 100 nm to 500 μm. Particularly in a case in which the first layer 130 is formed by the wet coating process, a relatively thick layer may be formed with ease by repeating the process.

(Second Layer 140)

As described above, one feature of the organic EL element is that the refractive index N₂ of the second layer 140 is greater than each of the refractive index [N′] of the transparent substrate 110, the refractive index [N″] of the light scattering layer, and the refractive index N₁ of the first layer 130. The refractive index N₂ of the second layer 140 is in a range of 1.65 to 2.70, for example.

The second layer 140 is made of a material other than molten glass. The second layer 140 may be made of oxide, nitride, or oxynitride, for example. The second layer 140 may be made of titanium oxide (TiO₂), titanium nitride (TiN), a titanium complex oxide (TiZrₓO_{y}), or the like, for example. However, the second layer 140 is made of a material different from that of the first layer 130.

In a case in which a material, having etching resistance with respect to an etchant that is used for an etching process to form the first electrode 150, is used for the second layer 140, it is possible to suppress the problem of the second layer 140 and the layers underneath, that is, the first layer 130 and the light scattering layer 120, from becoming damaged by a patterning process to form the first electrode.

A method of forming the second layer 140 is not limited to a particular method. For example, the second layer 140 may be formed by a dry coating process, such as PVD and CVD, or a wet coating process, such as dipping and sol-gel process.

(First Electrode 140)

The first electrode 140 requires a translucency of 80% or higher in order to extract light generated in the organic light emitting layer 160 to the outside. In addition, the first electrode 140 requires a high work function in order to inject a large amount of holes.

The first electrode 140 may be made of a material, such as ITO, SnO₂, ZnO, IZO (Indium Zinc Oxide), AZO (ZnO—Al₂O₃: aluminum doped zinc oxide), GZO (ZnO—Ga₂O₃: gallium doped zinc oxide), Nb doped TiO₂, Ta doped TiO₂, and the like, for example.

The thickness of the first electrode 140 is preferably 100 nm or greater.

The refractive index of the first electrode 140 is in a range of 1.9 to 2.2. For example, when ITO is used for the first electrode 140, the refractive index of the first electrode 140 may be reduced by increasing the carrier concentration. Although a standard commercially available ITO includes 10 wt % of SnO₂, the refractive index of ITO may be reduced by further increasing the Sn concentration. However, although the carrier concentration increases by increasing the Sn concentration, mobility and transmittance decrease. Accordingly, it is necessary to determine the amount of Sn considering the total balance.

(Organic Light Emitting Layer 160)

The organic light emitting layer 160 has a function to emit light, and generally, includes a hole injection layer, a hole transport layer, a light emitting layer, an electron transport layer, and an electron injection layer. As long as the organic light emitting layer 160 includes the light emitting layer, it may be apparent to those skilled in the art that not all of the other layers are necessary. Generally, the refractive index of the organic light emitting layer 160 is in a range of 1.7 to 1.8.

The hole injection layer preferably has a small difference in ionization potential in order to lower a hole injection barrier from the first electrode 150. When the injection efficiency of electric charges from the electrode to the hole injection layer increases, a driving voltage of the organic EL element 100 decreases, and the injection efficiency of the electric charges increases.

The material used for the hole injection layer may be a high molecular material or a low molecular material. Amongst the high molecular materials, polyethylenedioxythiophene (PEDOT: PSS) doped with polystyrene sulfonic acid (PSS) is often used. Amongst the low molecular materials, copper phthalocyanine (CuPc) of a phthalocyanine system is popularly used.

The hole transport layer has a function to transport the holes injected from the hole injection layer described above to the light emitting layer. For example, a triphenylamine derivative, N,N′-Bis(1-naphthyl)-N,N′-Diphenyl-1,1′-biphenyl-4,4′-diamine (NPD), N,N′-Diphenyl-N,N′-Bis[N-phenyl-N-(2-naphtyl)-4′-aminobiphenyl-4-yl]-1,1′-biphenyl-4,4′-diamine (NPTE), 1,1′-bis[(di-4-tolylamino)phenyl]cyclohexane (HTM2), and N,N′-Diphenyl-N,N′-Bis(3-methylphenyl)-1,1′-diphenyl-4,4′-diamine (TPD), and the like may be used for the hole transport layer.

The thickness of the hole transport layer is in a range of 10 nm to 150 nm, for example. The thinner the hole transport layer, the lower the driving voltage of the organic EL element may be. However, the thickness of the hole transport layer is generally in a range of 10 nm to 150 nm in view of the problem of short-circuiting between the electrodes.

The light emitting layer has a function to provide a field in which the injected electrons and holes recombine. The organic luminescent material may be a low molecular material or a high molecular material.

For example, a metal complex of quinoline derivative, such as tris(8-quinolinolate) aluminum complex (Alq₃), bis(8-hydroxy) quinaldine aluminum phenoxide (Alq′2OPh), bis(8-hydroxy) quinaldine aluminum-2,5-dimethylphenoxide (BAlq), mono(2,2,6,6-tetramethyl-3,5-heptanedionate)lithium complex (Liq), mono(8-quinolinolate)sodium complex (Naq), mono(2,2,6,6-tetramethyl-3,5-heptanedionate) lithium complex, mono(2,2,6,6-tetramethyl-3,5-heptanedionate) sodium complex, bis(8-quinolinolate) calcium complex (Caq₂), and the like, or a fluorescent substance, such as tetraphenylbutadiene, phenylquinacridone (QD), anthracene, perylene, coronene, and the like, may be used for the light emitting layer.

The host material may be a quinolinolate complex, and may particularly be an aluminum complex having 8-quinolinol and a derivative thereof as a ligand.

The electron transport layer has a function to transport electrons injected from the electrode. For example, a quinolinol aluminum complex (Alq₃), an oxadiazole derivative (for example, 2,5-bis(1-naphthyl)-1,3,4-oxadiazole (END), 2-(4-t-butylphenyl)-5-(4-biphenyl)-1,3,4-oxadiazole (PBD) or the like), a triazole derivative, a bathophenanthroline derivative, a silole derivative, and the like may be used for the electron transport layer.

For example, the electron injection layer may be formed by providing a layer in which alkali metal, such as lithium (Li), cesium (Cs), and the like is doped at an interface between the electron injection layer and the second electrode 170.

(Second Electrode 170)

The second electrode 170 is made of a metal having a small work function, or an alloy of such a metal. The second electrode 170 may be made of alkali metal, alkaline earth metal, a metal in group 3 of the periodic table, and the like. The second electrode 170 may be, for example, aluminum (Al), magnesium (Mg), or an alloy of such metals.

In addition, a co-vapor-deposited film of aluminum (Al) and magnesium silver (MgAg), or a laminated electrode in which aluminum (Al) is vapor-deposited on a thin layer of lithium fluoride (LiF) or lithium oxide (Li₂O), may be used for the second electrode 170. Further, a laminated layer of calcium (Ca) or barium (Ba) and aluminum (Al) may be used for the second electrode 170.

(Method of Manufacturing Organic EL Element in Embodiment)

Next, a description will be given of an example of a method of manufacturing the organic EL element in the embodiment, by referring to FIG. 2. FIG. 2 is a schematic flow chart of the method of manufacturing the organic EL element in the embodiment.

As illustrated in FIG. 2, the method of manufacturing the organic EL element in the embodiment includes step (step S110) to form the light scattering layer on the transparent substrate, step (step S120) to form the first layer on the light scattering layer, step (step S130) to form the second layer on the first layer, step (step S140) to form the first electrode on the second layer, step (step S150) to form the organic light emitting layer on the first electrode, and step (step S160) to form the second electrode on the organic light emitting layer. A detailed description of each step will be given hereinafter.

(Step S110)

First, the transparent substrate is prepared. As described above, generally, the glass substrate or the plastic substrate is used for the transparent substrate.

Next, the light scattering layer in which the scattering substances are dispersed in the glass base material is formed on the transparent substrate. The method of forming the light scattering layer is not limited to a particular method, but the method of forming the light scattering layer by the “frit paste method” will be described in particular. Of course, it may be apparent to those skilled in the art that the light scattering layer may be formed by other methods.

According to the frit paste method, a paste including a glass material called a frit paste is prepared (preparing step), the frit paste is coated on a surface of a substrate to be provided and patterned (patterning step), and the frit paste is baked (baking step). By these steps, a desired glass film is formed on the substrate to be provided. A brief description of each step will be given hereinafter.

(Preparing Step)

First, the frit paste that includes glass powder, a resin, a solvent, and the like is prepared.

The glass powder is made of a material that finally forms the base material of the light scattering layer. The composition of the glass powder is not limited to a particular composition, as long as a desired scattering characteristic is obtainable and the composition may take the form of the frit paste that may be baked. For example, the composition of the glass powder may include 20 mol % to 30 mol % of P₂O₅, 3 mol % to 14 mol % of S₂O₃, 10 mol % to 20 mol % of Bi₂O₃, 3 mol % to 15 mol % of TiO₂, 10 mol % to 20 mol % of Nb₂O₅, and 5 mol % to 15 mol % of WO₃, where the total amount of Li₂O, Na₂O and K₂O is 10 mol % to 20 mol %, and the total amount of the these components is 90 mol % or larger. In addition, the composition of the glass powder may include 0 to 30 mol % of SiO₂, 10 mol % to 60 mol % of B₂O₃, 0 to 40 mol % of ZnO, 0 to 40 mol % of Bi₂O₃, 0 to 40 mol % of P₂O₅, 0 to 20 mol % of alkali metal oxide, where the total amount of these components is 90 mol % or larger. A grain diameter of the glass powder is in a range of 1 μm to 100 μm, for example.

In order to control a thermal expansion characteristic of the light scattering layer that is finally obtained, a predetermined amount of filler may be added to the glass powder. For example, the filler may include particles of zircon, silica, alumina or the like, and generally have a grain diameter in a range of 0.1 μm to 20 μm.

For example, ethyl cellulose, nitrocellulose, acrylic resin, vinyl acetate, butyral resin, melamine resin, alkyd resin, rosin resin, or the like may be used for the resin. Ethyl cellulose, nitrocellulose, or the like may be used as a base resin. The strength of the frit paste coating layer may be improved by adding butyral resin, melamine resin, alkyd resin, or rosin resin.

The solvent has a function to dissolve the resin and to adjust the viscosity. For example, an ether type solvent (butyl carbitol (BC), butyl carbitol acetate (BCA), diethylene glycol di-n-butyl ether, dipropylene glycol butyl ether, tripropylene glycol butyl ether, butyl cellosolve acetate), an alcohol type solvent α-terpineol, pine oil, Dowanol), an ester type solvent (2,2,4-trimethyl-1,3-pentanediol monoisobutyrate), a phthalic acid ester type solvent (DBP (dibutyl phthalate), DMP (dimethyl phthalate), DOP (dioctyl phthalate)), or the like may be used for the solvent. Generally, α-terpineol or 2,2,4-trimethyl-1,3-pentanediol monoisobutyrate is mainly used as the solvent. Further, DBP (dibutyl phthalate, DMP (dimethyl phthalate), and DOP (dioctyl phthalate) also function as a plasticizer.

The frit paste may further be added with a surfactant in order to adjust the viscosity and to promote frit dispersion. In addition, a silane coupling agent may be used for surface modification.

Next, the frit paste in which the glass materials are uniformly dispersed is prepared by mixing the glass base material including the glass powder, the resin, the solvent, and the like.

(Patterning Step)

Next, the frit paste prepared by the above described method is coated on the transparent substrate and patterned. The method of coating and the method of patterning are not limited to particular methods. For example, the pattern of the frit paste may be printed on the transparent substrate using a screen printer. Alternatively, a doctor blade printing or a die coat printing may be used to print the pattern of the frit paste.

Thereafter, the frit paste layer is dried.

(Baking Step)

Next, the frit paste layer is baked. Generally, baking is performed by two steps. In the first step, the resin in the frit paste layer is decomposed and made to disappear, and in the second step, the glass powder is baked and softened.

The first step is performed under the atmosphere by maintaining the frit paste layer in a temperature range of 200° C. to 400° C. However, the process temperature may be varied depending on the resin material included in the frit paste. For example, in a case in which the resin is ethyl cellulose, the process temperature may be on the order of 350° C. to 400° C., and in a case in which the resin is nitrocellulose, the process temperature may be on the order of 200° C. to 300° C. The process time is generally on the order of approximately 30 minutes to 1 hour.

The second step is performed under the atmosphere by maintaining the frit paste layer in a temperature range of the softening temperature of the glass powder included in the frit paste layer ±30° C. The process temperature may be in a range of 450° C. to 600° C., for example. In addition, the process time is not limited to a particular time, and may be 30 minutes to 1 hour, for example.

After the second step, the glass powder is backed and softened, in order to form the base material of the light scattering layer. In addition, by the pores existing in the frit paste layer, the scattering substances uniformly dispersed in the base material may be obtained.

Thereafter, by cooling the transparent substrate, the light scattering layer is formed such that a side surface thereof is inclined from a top surface thereof towards a bottom surface thereof at an angle more gradual than a right angle.

The thickness of the light scattering layer that is finally obtained may be in a range of 5 μm to 50 μm.

(Step S120)

Next, the first layer is formed on the light scattering layer that is obtained by the steps described above.

The method of forming the first layer is not limited to a particular method, and a cry coating process or a wet coating process may be used.

The first layer is preferably formed by the wet coating process. The reason for this preference will be described hereinafter.

Generally, residual foreign matter included in the glass base material may often exist on the surface of the light scattering layer that is obtained by the steps described above. Large foreign matter may have a size on the order of 10 μm in diameter.

When such foreign matter exists on the surface of the light scattering layer, adhesion of each of the layers formed in subsequent steps, including the second layer, the first electrode, the organic light emitting layer, and the second electrode, may deteriorate.

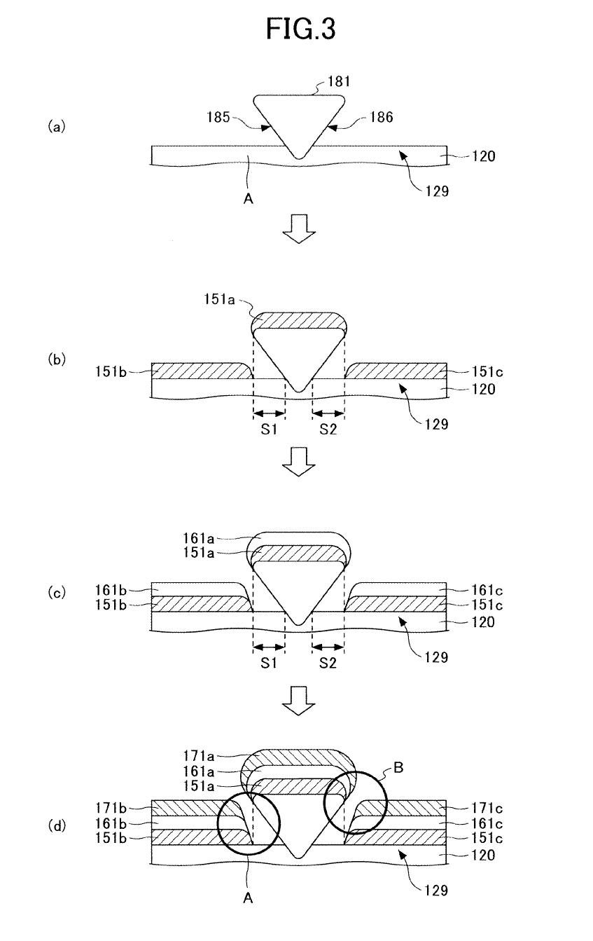

A more detailed description will be given of this problem, by referring to FIG. 3. In FIG. 3, for clarification purposes, the problem that occurs will be described using a simplified layer structure in which the illustration of the first layer 130 and the second layer 140 is omitted.

As illustrated in FIG. 3(a), foreign matter 181 exists on a surface 129 of the light scattering layer 120. The foreign matter 181 has a first side surface 185 and a second side surface 186. The first side surface 185 may extend such that the grain diameter of the foreign matter 181 decreases from the top side towards the bottom side. Similarly, the second side surface 186 may extend such that the grain diameter of the foreign matter 181 decreases from the top side towards the bottom side.

Because the first electrode 150 is formed in this state, when the layer material is deposited on the surface 129 of the light scattering layer 120, the layer material is deposited on the top part of the foreign matter 181 to form a layer part 151a, and is also deposited on the top part of the surface 129 of the light scattering layer 120 to form layer parts 151b and 151c, as illustrated in FIG. 3(b).

Due to the existence of the first side surface 185 of the foreign matter 181, the layer material is uneasily deposited in a region S1 of the surface 129 of the light scattering layer 120. For this reason, the layer part 151b that is formed does not completely cover the region S1 of the surface 129 of the light scattering layer 120, as illustrated in FIG. 3(b). Similarly, due to the existence of the second side surface 186 of the foreign matter 181, the layer material is uneasily deposited in a region S2 of the surface 128 of the light scattering layer 120. For this reason, the layer part 151c that is formed does not completely cover the region S2 of the surface 129 of the light scattering layer 120, as illustrated in FIG. 3(b).

Next, when the layer material of the organic light emitting layer 160 is deposited on the top part of the first electrode 150 in order to form the organic light emitting layer 160, the layer material is deposited on the top part of each of the layer parts 151a, 151b, and 151c, as illustrated in FIG. 3(c). As a result, layer parts 161a, 161b, and 161c of the organic light emitting layer 160 are formed.

In this case, due to the existence of the foreign matter 181, the layer parts 161b and 161c are uneasily formed above the regions S1 and S2 on the surface 129 of the light scattering layer 120. Particularly, the layer part 161a of the organic light emitting layer 160 tends to completely cover the surface part 151a of the first electrode 150 and also extend to the side part of the layer part 151a. Further, because this layer part 161a interferes with the deposition of the layer material of the organic light emitting layer 160, regions in which the layer parts 161b and 161c are formed become smaller than the regions in which the layer parts 151b and 151c of the first electrode 150 are formed.

Next, when the layer material of the second electrode 170 is deposited on the top part of the organic light emitting layer 160 in order to form the second electrode 170, the layer material is deposited on the top part of each of the layer parts 161a, 161b, and 161c of the organic light emitting layer 160, as illustrated in FIG. 3(d). As a result, layer parts 171a, 171b, and 171c of the second electrode 170 are formed.

In this case, due to the existence of the foreign matter 181, the layer parts 171b and 171c are uneasily formed above the regions S1 and S2 on the surface 129 of the light scattering layer 120. Particularly, the layer part 171a of the second electrode 170 tends to completely cover the surface part 161a of the organic light emitting layer 160 and also extend to the side part of the layer part 161a. Further, because this layer part 171a interferes with the deposition of the layer material of the second electrode 170, regions in which the layer parts 171b and 171c are formed become smaller than the regions in which the layer parts 161b and 161c of the organic light emitting layer 160 are formed.

According to the layer structure described above, there is a problem in that the possibility of the layer part 151b of the first electrode 150 making contact with the layer part 171b of the second electrode 170 increases at a part surrounded by a circular mark A in FIG. 3(d). In addition, there is a problem in that the possibility of the layer part 151a of the first electrode 150 making contact with the layer part 171c of the second electrode 170 increases at a part surrounded by a circular mark B in FIG. 3(d).

Hence, the existence of the foreign matter 181 on the light scattering layer 120 may deteriorate the adhesion of each of the layers formed in the subsequent steps. In addition, when the effects of the foreign matter 181 become notable, the problem of two electrodes becoming short-circuited may occur. Furthermore, when such a short-circuit occurs, the desired characteristics cannot be obtained in the organic LED element that is finally obtained.

However, in the case in which the first layer 130 is formed by the wet coating process, even when foreign matter exists on the light scattering layer 120, the state of each of the layers formed in the subsequent steps may be adequately controlled.

Unlike the sputtering or the dry coating process, according to the wet coating process, the layer material may sufficiently reach even the regions S1 and S2 that may be shaded by the foreign matter 181, and consequently, the state of each of the layers formed in the subsequent steps may be adequately controlled.

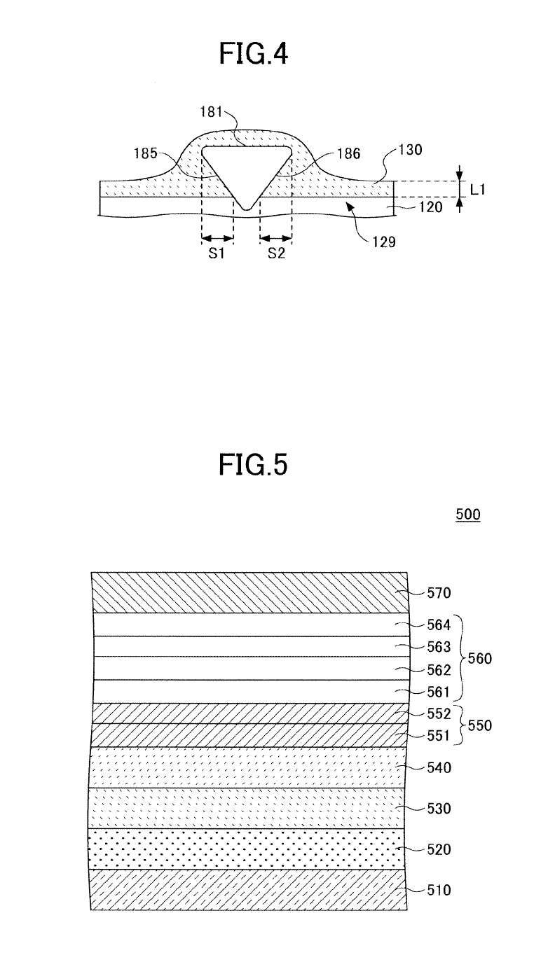

FIG. 4 is a diagram schematically illustrating an example of a layer configuration when the first layer 130 is formed by the wet coating process in the case in which the foreign matter 181 exists on the surface 129 of the light scattering layer 120.

As illustrated in FIG. 4, the foreign matter 181 having the configuration described above with reference to FIG. 3 exists on the surface 129 of the light scattering layer 120. For this reason, the regions S1 and S2 shaded by the first and second side surfaces 185 and 186 of the foreign matter 181 exist on the surface 129 of the light scattering layer 120.

However, in FIG. 4, the first layer 130 is formed by the wet coating process. In this case, the first layer 130 may be formed on the top part of the surface 129 of the light scattering layer 120 so as to cover the foreign matter 181 and to further cover the regions S1 and S2 on the surface 129 of the light scattering layer 120.

In a case in which the second layer 140 up to the second electrode 160 are successively formed on the top part of the first layer 130 that is formed in the above described manner, each of the successively formed layers may be configured to be continuous and relatively smooth.

Accordingly, the problem of adhesion of each of the layers that may deteriorate, and particularly the increased possibility of the first and second electrodes 150 and 170 becoming short-circuited, caused by the existence of the foreign matter 181, may be suppressed significantly by the existence of the first layer 130.

Next, a description will be given of a method of forming the first layer using a sol-gel solution that includes an organic metal solution and organic metal particles, as an example of the wet coating process. Of course, the first layer may be formed by other wet coating processes.

In the case in which the first layer is formed using the sol-gel solution that includes the organic metal solution and the organic metal particles, the first layer may be formed by step (coating step) to coat the sol-gel solution on the light scattering layer, step (drying step) to dry the coated sol-gel layer, and step (heat treatment step) to subject the dried sol-gel layer to a heat treatment. Next, a description will be given of each of these steps.

(Coating Step)

First, the sol-gel solution is coated on the light scattering layer. The sol-gel solution includes the organic metal solution and the organic metal particles.

For example, the organic metal solution may be an alkoxide or an organic complex of titanium, niobium, zirconium, tantalum, and/or silicon.

For example, the organic metal particles may be oligomer or particles of organic titanium, organic niobium, organic zirconium, and/or organic tantalum. In addition, the sol-gel solution is not limited to a particular solution, and water and/or an organic solvent may be used for the solution.

The organic metal solution is not limited to but may include titanium alkoxide such as titanium tetramethoxide, titanium tetraethoxide, titanium tetranormalpropoxide, titanium tetraisopropoxide, titanium tetranormalbutoxide, titanium tetraisobutoxide, titanium di-isopropoxy-di-normalbutoxide, titanium di-tert-butoxy-di-isopropoxide, titanium tetra-tert-butoxide, titanium tetrapentoxide, titanium tetrahexoxide, titanium tetraheptoxide, titanium tetraisooctyloxide, tetrastearylalkoxytitanate, and the like, titanium tetracycloalkoxide such as titanium tetracyclohexoxide, titanium aryloxide such as titanium tegraphenoxide, titanium acylate such as hydroxy titanium stearate, titanium chelate such as di-propoxytitanium-bis-(acetylacetonate), titanium tetraacetylacetonate, titanium di-2-ethylhexoxy-bis-(2-ethyl-3-hydroxyhexoxide), titanium di-isopropoxy-bis-(ethylacetoacetate), titanium di-isopropoxy-bis-(triethanolaminate), titanium ammonium lactate, and titanium lactate, alkoxyzirconium such as zirconium tetranormalpropoxide and zirconium tegranormalbutoxide, zirconium acylate such as zirconium tributoxymonostearate, zirconium chloride compound and zirconium aminocarboxylic acid, zirconium chelate such as zirconium tetraacetylacetonate, zirconium tributoxy monoacetylacetonate, zirconium di-butoxy-bis-(ethylacetoacetate), and zirconium tetraacetylacetonate, alkoxysilanes such as tetramethoxy silane, methyltrimethoxy silane, di-methyl-di-methoxy silane, phenyltrimethoxy silane, di-phenyl-di-methoxy silane, hexyltrimethoxy silane, decyltrimethoxy silane, vinyltrimethoxy silane, 2-(3,4-epoxycyclohexyl)ethyltrimethoxy silane, 3-glycidoxypropylmethyl-di-methoxy silane, 3-(glycidyloxy) propyltrimethoxy silane, trifluoropropyltrimethoxy silane, p-styryltrimethoxy silane, 3-methacryloxypropylmethyl-di-methoxy silane, 3-methacryloxypropyltrimethoxy silane, 3-acryloxypropyltrimethoxy silane, N-2-(aminoethyl)-3-aminopropylmethyl-di-methoxy silane, N-3-(aminoethyl)-3-aminopropyltrimethoxy silane, N-phenyl-3-aminopropyltrimethoxy silane, 3-mercaptopropylmethyl-di-methoxy silane, 3-mercaptopropyltrimethoxy silane, tetraethoxy silane, methyltriethoxy silane, di-methyl-di-ethoxy silane, phenyltriethoxy silane, di-phenyl-di-ethoxy silane, 3-methacryloxypropylmethyl-di-ethoxy silane, 3-methacryloxypropyltriethoxy silane, hexyltriethoxy silane, vinyltriethoxy silane, 3-glycidoxypropylmethyl-di-ethoxy silane, 3-glycidoxypropyltriethoxy silane, N-2-(aminoethyl)-3-aminopropyltriethoxy silane, 3-aminopropyltrimethoxy silane, 3-triethoxysilyl-N-(1,3-di-methiyl-butylidene) propylamine, 3-ureidopropyltriethoxy silane, 3-isocyanatepropyltriethoxy silane, tetranormalpropoxy silane, tetraisopropoxy silane, tetranormalbutoxy silane, tetraospbutoxy silane, di-isopropoxy-di-normalbutoxy silane, di-tert-butoxy-di-isopropoxy silane, tetra-tert-butoxy silane, tetrapentoxy silane, tetrahexoxy silane, tetraheptopxy silane, tetraisooctyloxy silane, tetrastearylalkoxy silane, and the like, silazanes such as hexamethyl-di-salazane and the like, and a solvent of alcohol, ether, ketone, and hydrocarbons.

The alkoxides or chelate compounds of titanium, niobium, zirconium, tantalum, and silicon, which are organic metals, are preferably subjected to polycondensation, in order to use an oligomer of titanium, niobium, zirconium, tantalum, and silicon compounds. The method of polycondensation is not limited to a particular method, and preferably, water may be caused to react within an alcohol solution. The polycondensation may suppress generation of cracks when the layers are formed, and the layers may be made thin. In addition, by mixing an organic silane compound, the generation of cracks may be suppressed in particular when the layers are formed, and the layers may be made thin in particular. Further, the polycondensation enables the refractive index of the layers to be adjusted.

The method of coating the sol-gel solution is not limited to a particular method. The sol-gel solution may be coated on the light scattering layer using a general coating forming apparatus (applicator or the like).

(Drying Step)

Next, the sol-gel layer is formed by subjecting the sol-gel solution coated on the light scattering layer to a drying process. The drying conditions are not limited to particular conditions. For example, the drying process may dry the sol-gel solution coated on the light scattering layer on the transparent substrate, at a temperature in a range of 80° C. to 120° C., for a time on the order of 1 minute to 1 hour.

(Heat Treatment Step)

Next, the sol-gel layer subjected to the drying process is held at a high temperature. As a result, the solvent within the sol-gel layer is completely evaporated, decomposed, and/or made to disappear, and the first layer is formed by the oxidation and bonding of the organic metal compound within the sol-gel layer.

The heat treatment conditions are not limited to particular conditions. For example, the substrate holding temperature may be in a range of 450° C. to 550° C., and the substrate holding time may be in a range of 10 minutes to 24 hours.

In the case in which the first layer 130 is formed by the method described above, even when the foreign matter exists on the light scattering layer, the sol-gel solution reaches the regions of the light scattering layer shaded by the foreign matter. For this reason, the steps described above may finally form a continuous first layer that totally covers the light scattering layer and the foreign matter, as illustrated in FIG. 4.

The first layer may be formed by the steps described above.

(Step S130)

Next, the second layer is formed on the first layer that is formed by the steps described above. The method of forming the second layer is not limited to a particular method. For example, the second layer may be formed deposition methods such as sputtering, deposition, vapor deposition, and the like.

The method of forming the second layer is not limited to a particular method. For example, the second layer may be formed by a dry coating process, such as sputtering, deposition, and vapor deposition (PVD and CVD).

Next, the first electrode (anode) is formed on the second layer that is formed by the steps described above.

The method of forming the first electrode is not limited to a particular method. For example, the first electrode may be formed by a method such as sputtering, deposition, vapor deposition, and the like. In addition, the first electrode may be patterned.

As described above, the material used for the first electrode may be ITO or the like. In addition, the thickness of the first electrode is not limited to a particular thickness, and the thickness of the first electrode may be in a range of 50 nm to 1.0 μm, for example.

A stacked structure including the transparent substrate, the light scattering layer, the first layer, the second layer, and the first electrode that are formed by the steps described above, is hereinafter also be referred to as a “translucent substrate”. The specification of the organic light emitting layer that is to be formed in the next step varies in accordance with the usage of the organic EL element that is finally obtained. Thus, customarily, there are many cases in which the “translucent substrate” is distributed as it is in a market as an intermediate product, and the following steps may be omitted in many cases.

(Step S150)

When manufacturing the organic EL element, the organic light emitting layer is formed next in order to cover the first electrode. The method of forming the organic light emitting layer is not limited to a particular method, and deposition and/or coating may be used, for example.

(Step S160)

Next, the second electrode is formed on the organic light emitting layer. The method of forming the second electrode is not limited to a particular method, and deposition, sputtering, vapor deposition, or the like may be used, for example.

The organic EL element 100 illustrated in FIG. 1 is manufactured by the steps described above.

The method of manufacturing the organic EL element described above is merely an example, it may be apparent to those skilled in the art that the organic EL element may be manufactured by other methods.

### Practical Examples

Practical examples of the embodiment will now be described.

### Practical Example 1

A light extraction characteristic of the LED element in accordance with the embodiment was evaluated by simulation.

FIG. 5 is a cross sectional view schematically illustrating a structure of the LED element used for the simulation.

As illustrated in FIG. 5, an LED element 500 used in this practical example 1 includes a transparent substrate 510, a light scattering layer 520, a first layer 530, a second layer 540, a first electrode 550, an organic light emitting layer 560, and a second electrode 570 that are stacked in this order. This LED element 500 is an example of a red light emitting element.

The transparent substrate 510 is assumed to be made of soda-lime. In addition, the light scattering layer 520 is assumed to be made of a glass base material including, in mol % representation, 23.9% of P₂O₅, 12.4% of B₂O₃, 5.2% of Li₂O, 15.6% of Bi₂O₃, 16.4% of Nb₂O₅, 21.6% of ZnO, and 4.9% of ZrO₂. Because the transparent substrate 510 and the light scattering layer 520 may be regarded as being media for finally outputting light, thicknesses thereof are assumed to be 0.

The first layer 520 is assumed to be made of titanium oxide (TiO₂), with a thickness of 300 nm.

The second layer 530 is assumed to be made of titanium zirconium complex oxide (TiZrₓO_{y}), with a thickness variable in a range of 10 nm to 200 nm.

The first electrode 550 is assumed to have a 2-layer structure including a first layer 551 and a second layer 552, both made of ITO. In addition, the thickness of both layers is assumed to be 75 nm. The first electrode 550 is made to have the 2-layer structure, because in the actual LED element, the ITO electrode may be anticipated to have different refractive indexes at the upper layer side and the bottom layer side.

The organic light emitting layer 560 is assumed to have a 4-layer structure including a hole transport layer 561, a light emitting layer 562, an electron transport layer 563, and an electron injection layer 564.

The hole transport layer 561 is assumed to be made of α-NPD (N,N′-Di(1-naphthyl)-N,N′-diphenylbenzidine), with a thickness variable in a range of 10 nm to 200 nm. The light emitting layer 562 is assumed to be made of Alq₃ and red dye (DCJTN), with a thickness of 20 nm. The electron transport layer 563 is assumed to be made of Alq₃, with a thickness variable in a range of 10 nm to 200 nm. The electron injection layer 564 is assumed to be made of LiF, with a thickness of 0.5 nm.

The second electrode 570 is assumed to be formed by an aluminum layer having a thickness of 80 nm.

Table 1 shows values of the refractive index n (real part of complex refractive index) and the attenuation coefficient k (imaginary part of complex refractive index) of each of the layers used for the simulation, with respect to the g-line (wavelength of 436 nm), F-line (wavelength of 486 nm), d-line (wavelength of 588 nm), and C-line (wavelength of 656 nm). These values indicate results measured by the ellipsometry.

TABLE 1

| | Complex | | | | |
|---|---|---|---|---|---|
| | Refractive | g-Line | F-Line | d-Line | C-Line |
| Layer | Index | 436 nm | 486 nm | 588 nm | 656 nm |
| Transparent | n | 1.528 | 1.523 | 1.517 | 1.515 |
| Substrate | k | 0.0E+00 | 0.0E+00 | 0.0E+00 | 0.0E+00 |
| Light | n | 1.993 | 1.968 | 1.938 | 1.927 |
| Scattering | k | 9.1E−07 | 7.6E−08 | 1.7E−09 | 2.6E−10 |
| Layer | | | | | |
| First Layer | n | 1.746 | 1.725 | 1.702 | 1.693 |
| | k | 4.0E−05 | 3.1E−05 | 2.2E−05 | 1.8E−05 |
| Second | n | 2.464 | 2.406 | 2.344 | 2.321 |
| Layer | k | 3.7E−04 | 3.9E−05 | 7.6E−07 | 8.6E−08 |
| First | n | 2.086 | 2.042 | 1.962 | 1.909 |
| Electrode | k | 1.5E−02 | 1.5E−02 | 1.8E−02 | 2.2E−02 |
| (Bottom | | | | | |
| Part) | | | | | |
| First | n | 2.108 | 2.065 | 2.000 | 1.965 |
| Electrode | k | 4.0E−03 | 5.7E−03 | 1.0E−02 | 1.5E−02 |
| (Top Part) | | | | | |
| Hole | n | 1.962 | 1.886 | 1.808 | 1.782 |
| Transport | k | 1.3E−04 | 3.4E−08 | 1.6E−13 | 3.6E−16 |
| Layer | | | | | |
| Light | n | 1.777 | 1.698 | 1.682 | 1.661 |
| Emitting | k | 2.4E−02 | 2.3E−03 | 3.2E−03 | 0.0E+00 |
| Layer | | | | | |
| Electron | n | 1.857 | 1.766 | 1.712 | 1.696 |
| Transport | k | 5.1E−02 | 0.0E+00 | 1.4E−03 | 1.7E−03 |
| Layer | | | | | |
| Electron | n | 1.397 | 1.395 | 1.392 | 1.391 |
| Injection | k | 0.0E+00 | 0.0E+00 | 0.0E+00 | 0.0E+00 |
| Layer | | | | | |
| Second | n | 0.808 | 1.098 | 1.606 | 2.023 |
| Electrode | k | 6.1E+00 | 6.8E+00 | 7.9E+00 | 8.8E+00 |

The radiance (W/Sr·m²) of light emitted from the side of the transparent substrate 510 of the LED element 500 having the layer structure illustrated in FIG. 5, in a range of the wavelength of 400 nm to 800 nm, is calculated by simulation. The thickness of each of the layers having the variable thickness is added to a variable, and a combination of the thicknesses for a case in which a maximum radiance of light emitted is obtained in a direction perpendicular to the element is calculated in the simulation. Actually, the light incident to the light scattering layer is scattered, and reflected at the interface between the light scattering layer and the glass substrate, and thus, the luminance of light perpendicularly emitted from the substrate and the luminance of light perpendicularly incident to the light scattering layer do not match. However, it may be regarded that, when the luminance of light perpendicularly incident to the light scattering layer is high, the luminance of light emitted to the atmosphere perpendicularly from the substrate also becomes high. In a case in which the element is formed on the substrate having the glass scattering layer having the high refractive index, the angle dependency of the emitted light follows the Cos θ rule, and thus, it may be estimated that the amount of luminous flux of the emitted light as a whole is large when the luminance of the light emitted in the perpendicular direction from the substrate is high.

In addition, a SETFOS (vendor: Cybernet Systems) manufactured by FLUXiM is used for the simulation.

(Results)

The results of the simulation are shown in a column labeled “Case 3” in the following Table 2.

TABLE 2

| | Layer Thickness | | | | | | | |
|---|---|---|---|---|---|---|---|---|
| | | | Hole | Light | Electron | Electron | | |
| | First | Second | Transport | Emitting | Transport | Injection | Calculated Result | |
| | Layer | Layer | Layer | Layer | Layer | Layer | Radiance | |
| Case | 530 (nm) | 540 (nm) | 561 (nm) | 562 (nm) | 563 (nm) | 564 (nm) | (W/Sr · m²) | Magnification |
| Case 1 | — | — | 85 | 20 | 70 | 0.5 | 9031 | 1 |
| Case 2 | — | 70 | 90 | 20 | 70 | 0.5 | 10907 | 1.21 |
| Case 3 | 300 | 70 | 85 | 20 | 70 | 0.5 | 11683 | 1.29 |

Table 2 shows the radiance of light emitted perpendicularly from the element, for a case (Case 1) in which no first layer 530 and no second layer 540 are provided in FIG. 5, and also for a case (Case 2) in which the second layer 540 is provided but no first layer 530 is provided, for comparison purposes. In addition, the column labeled “Magnification” for each case indicates the magnification of the radiance for each case with reference to the radiance (W/Sr·m²) obtained for the Case 1.

Furthermore, Table 2 also shows the thickness of each layer when the maximum radiance is obtained for each case.

From Table 2, it may be seen that the radiance is improved to approximately 1.3 times for the Case 3 provided with the first and second layers 530 and 540, when compared to the Case 1 in which no first and second layers 530 and 540 are provided. Hence, it may be confirmed that the radiance (W/Sr·m²) of the light emitted from the side of the transparent substrate 510 greatly improves by the provision of the first and second layers 530 and 540.

### Practical Example 2

The light extraction characteristic of the LED element in accordance with the embodiment is evaluated by a method similar to that for the practical example 1.

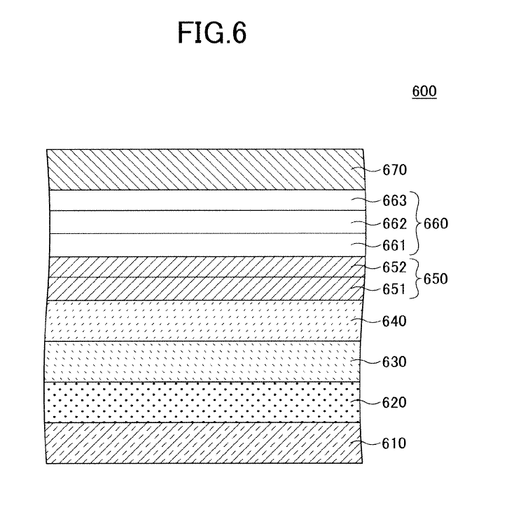

FIG. 6 is a cross sectional view schematically illustrating the structure of the LED element used for simulation.

As illustrated in FIG. 6, an LED element 600 used in this practical example 2 includes a transparent substrate 610, a light scattering layer 620, a first layer 630, a second layer 640, a first electrode 650, an organic light emitting layer 660, and a second electrode 670 that are stacked in this order. This LED element 600 is an example of a green light emitting element.

The transparent substrate 610 is assumed to be made of soda-lime. In addition, the light scattering layer 620 is assumed to be made of a glass base material including, in mol % representation, 23.9% of P₂O₅, 12.4% of B₂O₃, 5.2% of Li₂O, 15.6% of Bi₂O₃, 16.4% of Nb₂O₅, 21.6% of ZnO, and 4.9% of ZrO₂. Because the transparent substrate 610 and the light scattering layer 620 may be regarded as being media for finally outputting light, as described above, thicknesses thereof are assumed to be 0.

The first layer 630 is assumed to be made of titanium oxide (TiO₂), with a thickness of 300 nm.

The second layer 640 is assumed to be made of titanium zirconium complex oxide (TiZrₓO_{y}), with a thickness variable in a range of 10 nm to 200 nm.

The first electrode 650 is assumed to have a 2-layer structure including a first layer 651 and a second layer 652, both made of ITO. In addition, the thickness of both layers is assumed to be 75 nm.

The organic light emitting layer 660 is assumed to have a 3-layer structure including a hole transport layer 661, a light emitting layer 662, and an electron injection layer 663.

The hole transport layer 661 is assumed to be made of NPD, with a thickness variable in a range of 10 nm to 200 nm. The light emitting layer 662 is assumed to be made of Alq₃, with a thickness variable in a range of 10 nm to 200 nm. The electron injection layer 663 is assumed to be made of LiF, with a thickness of 0.5 nm.

The second electrode 670 is assumed to be formed by an aluminum layer having a thickness of 80 nm.

(Results)

The results of the simulation are shown in a column labeled “Case 6” in the following Table 3.

TABLE 3

| | Layer Thickness | | | | | | |
|---|---|---|---|---|---|---|---|
| | | | Hole | Light | Electron | | |
| | First | Second | Transport | Emitting | Injection | Calculated Result | |
| | Layer | Layer | Layer | Layer | Layer | Radiance | |
| Case | 630 (nm) | 640 (nm) | 661 (nm) | 662 (nm) | 664 (nm) | (W/Sr · m²) | Magnification |
| Case 4 | — | — | 75 | 70 | 0.5 | 14950 | 1 |
| Case 5 | — | 45 | 65 | 70 | 0.5 | 16358 | 1.09 |
| Case 6 | 300 | 45 | 65 | 70 | 0.5 | 16683 | 1.12 |

Table 3 shows the radiance of light emitted perpendicularly from the element, for a case (Case 4) in which no first layer 630 and no second layer 640 are provided in FIG. 6, and also for a case (Case 5) in which the second layer 640 is provided but no first layer 630 is provided, for comparison purposes. In addition, the column labeled “Magnification” for each case indicates the magnification of the radiance for each case with reference to the radiance (W/Sr·m²) obtained for the Case 4.

Furthermore, Table 3 also shows the thickness of each layer when the maximum radiance is obtained for each case.

From Table 3, it may be seen that the radiance is improved to approximately 1.1 times for the Case 6 provided with the first and second layers 630 and 640, when compared to the Case 4 in which no first and second layers 630 and 640 are provided. Hence, it may be confirmed that the radiance (W/Sr·m²) of the light emitted from the side of the transparent substrate 610 greatly improves by the provision of the first and second layers 630 and 640.

The present invention may provide an organic EL element in which the light emitting efficiency is improved when compared to that of the conventional case. The present invention may also provide a translucent substrate for use in such an organic EL element, and a method of manufacturing an organic LED element.

The present invention may be applied to the organic EL element that is used in light emitting devices and the like.

The organic EL element and the translucent substrate are described above with reference to the embodiments, however, it may be apparent to those skilled in the art that the present invention is not limited to the above embodiments, and various variations and modifications may be made without departing from the spirit and scope of the present invention.

What is claimed is:

1. An organic LED element comprising:
a transparent substrate;
a light scattering layer formed on the transparent substrate;
a transparent first electrode formed on the light scattering layer;
an organic light emitting layer formed on the first electrode; and
a second electrode formed on the organic light emitting layer,
wherein the light scattering layer includes a base material made of glass, and a plurality of scattering substances dispersed in the base material, wherein the light scattering layer has a refractive index [N″] greater than a refractive index [N′] of the transparent substrate;
a first layer and a second layer are arranged between the light scattering layer and the first electrode, such that the first layer is closer to the light scattering layer than the second layer;
the first layer is made of a material other than molten glass, and has a first refractive index N₁;
the second layer is made of a material other than the molten glass, and has a second refractive index N₂;
the first refractive index N₁ is greater than the refractive index [N′] of the transparent substrate; and
the second refractive index N₂ is greater than each of the refractive index [N′] of the transparent substrate, the refractive index [N″] of the light scattering layer, and the first refractive index N.

2. The organic LED element as claimed in claim 1, wherein the refractive index [N″] of the light scattering layer is greater than the first refractive index N.

3. The organic LED element as claimed in claim 1, wherein at least one of the first layer and the second layer is made of a metal oxide.

4. A translucent substrate comprising:
a transparent substrate;
a light scattering layer formed on the transparent substrate;
a first layer formed on the light scattering layer;
a second layer formed on the first layer; and
a transparent first electrode formed on the second layer;
wherein the light scattering layer includes a base material made of glass, and a plurality of scattering substances dispersed in the base material, wherein the light scattering layer has a refractive index [N″] greater than a refractive index [N′] of the transparent substrate;
the first layer is made of a material other than molten glass, and has a first refractive index N₁;
the second layer is made of a material other than the molten glass, and has a second refractive index N₂;
the first refractive index N₁ is greater than the refractive index [N′] of the transparent substrate; and
the second refractive index N₂ is greater than each of the refractive index [N′] of the transparent substrate, the refractive index [N″] of the light scattering layer, and the first refractive index N.

5. The translucent substrate as claimed in claim 4, wherein the refractive index [N″] of the light scattering layer is greater than the first refractive index N₁.

6. The translucent substrate as claimed in claim 4, wherein at least one of the first layer and the second layer is made of a metal oxide.

7. A method of manufacturing an organic LED element comprising a transparent substrate, a light scattering layer formed on the transparent substrate, a transparent first electrode formed on the light scattering layer, an organic light emitting layer formed on the first electrode, and a second electrode formed on the organic light emitting layer, the method comprising:
forming a first layer and a second layer between the light scattering layer and the first electrode;
wherein the first layer is formed by a wet coating process at a position closer to the light scattering layer than the second layer, using a material other than molten glass and having a first refractive index N₁;
the second layer is formed using a material other than the molten glass and having a second refractive index N₂;
the light scattering layer includes a base material made of glass, and a plurality of scattering substances dispersed in the base material, and has a refractive index [N″] greater than a refractive index [N′] of the transparent substrate;
the first refractive index N₁ is greater than the refractive index [N′] of the transparent substrate; and
the second refractive index N₂ is greater than each of the refractive index [N′] of the transparent substrate, the refractive index [N″] of the light scattering layer, and the first refractive index N.

8. The method of manufacturing the organic LED element as claimed in claim 7, wherein the refractive index [N″] of the light scattering layer is greater than the first refractive index N₁.

9. The method of manufacturing the organic LED element as claimed in claim 7, wherein at least one of the first layer and the second layer is made of a metal oxide.
